(19) United States
(12) Patent Application Publication
(10) Pub. No.: US 2003/0077401 A1
(43) Pub. Date: Apr. 24, 2003

(54) System and method for deposition of coatings on a substrate

(76) Inventors: Alexader Igorevich Dodonov, Istra Moskovskaya obl (RU); Valery Diamant, Kazrin (IL); Valery Mikhailovich Bachkov, Moscow (RU)

Correspondence Address: JACOBSON HOLMAN PLLC, 400 SEVENTH STREET N.W., SUITE 600, WASHINGTON, DC, 20004, US

(21) Appl. No.: 10/181,930

(22) PCT Filed: Jan. 25, 2001
(86) PCT No.: PCT/RU01/00027

(30) Foreign Application Priority Data
Jan. 27, 2000 (IL) 134255

(51) Int. Cl. C23C 16/00

(52) U.S. Cl. 427/569; 427/248.1; 118/723 R; 118/723 VE; 118/723 HC

(57) ABSTRACT

The present invention relates to a system and method for deposition of coatings on a substrate. More particularly, the invention concerns a system and method for low-temperature deposition of corrosion-proof, wear-resistant ion-plasma coatings.

A system for deposition of an ion plasma coating on a substrate, said system comprising: a housing defining a vacuum chamber and having access means for the introduction and retrieval of a substrate to be coated; a plasma vacuum deposition (PVD) source communicating with the interior of said housing; an electrically conductive support on which said substrate is placed; a gas ion-plasma source cathode assembly communicating with said chamber in spaced-apart relationship to said support; a first power supply electrically connected to said support; a second power supply electrically connected to said cathode assembly, and a third power supply of additional discharge electrically connectable to said cathode assembly, wherein said power supplies are operative to effect pulsed discharge on said gas ion-plasma source cathode assembly or pulsed accelerating voltage on said support.

### FIELD OF THE INVENTION

The present invention relates to a system and method for deposition of coatings on a substrate. More particularly, the invention concerns a system and method for low-temperature deposition of corrosion-proof, wear-resistant ion-plasma coatings.

### BACKGROUND OF THE INVENTION

At present, various coatings are deposited on instruments, machine and mechanism parts and other industrial articles, for surface modification through the application of wear-resistant, protective, corrosion-proof surface layers. Different methods are used for the deposition of decorative coatings, coatings having preset electric and magnetic properties, and other special-purpose coatings.

During recent years, electro-physical plasma vacuum deposition (PVD) methods for depositing wear-resistant coatings, based on chemical reactions between atoms or ions of metals and active gases enclosed in a vacuum chamber, have become popular. PVD methods offer a wide range of technological potentials, as they are based on the transition of the coating material to a vapor or plasma state in vacuum by means of so-called “physical” methods, including thermal evaporation, electron or ion-radiation evaporation, ion sputtering (including magnetron), arc vapor deposition, and the like, followed by condensation on a substrate, normally in the presence of an electric gas discharge. Such methods make it possible to obtain coatings having a highly uniform thickness and good adhesion to the substrate. Important advantages of these methods are their ecological cleanliness and the absence of chemically harmful and toxic wastes and radiation.

Among the above-mentioned PVD methods, the vacuum arc ion-plasma method should be noted as one of the most promising. It is based on a plasma flux generated from the sputtered material through the high precision arc discharge on a cold cathode. In this method, the plasma flux is highly ionized; for some materials, the degree of ionization is almost 100%. The plasma contains a considerable amount of particles, which are ionized twice and three times. The high plasma ionization level in arc method provides an important advantage in comparison with other PVD methods wherein the substance fluxes are either neutral or feature a low degree of ionization, necessitating special measures in order to increase it.

A high degree of ionization enables control of the flux through electro-magnetic fields for monitoring and controlling the energy of atoms that reach the substrate and for increasing the activity of the evaporated material in forming compounds with the reactive gas. These methods allow the formation of coatings and surface layers on structures, which cannot otherwise be reached. To form a coating, settling vapor or plasma fluxes are guided to the substrate.

The deposition process can be divided into three stages: cleaning of the substrate surface, heating of articles to be coated, and deposition of the coatings.

In the first stage, the substrate surface is usually bombarded with accelerated ions to achieve the so-called “ion cleaning.” Such bombarding causes impurities to sputter from the surface when the atomic layers near the surface are activated. For this purpose, most of the PVD methods employ either glow discharge, in which the treated article is used as a cathode, or additional ion sources that generate fluxes of accelerated ions. In the electrical arc vacuum PVD method of coating, the same plasma flux is used for ion decontamination and for coating deposition. Such a plasma flux can be used for these two purposes, due to its high degree of ionization. For ion decontamination, an accelerating voltage of up to 1000-1500 V is applied to the substrate in a sufficiently deep vacuum having a pressure of 0.0001 Hg/mm and less. The cathode material ions are accelerated close to the substrate in the Debbie layer and bombard its surface.

In the second stage, the articles are heated. In order to provide quality hard coatings, the temperature of me articles is usually raised to 450° C. and more. The articles are heated either indirectly, in traditional ion plating and sputtering methods, with additional thermal or radiation heaters, or through the kinetic energy of accelerated ions bombarding their surfaces. In order to heat articles by means of bombarding ions, as in the ion decontamination process, either additional sources of ions are used, or highly ionized plasma ions are accelerated by negative high voltage applied to the substrate. The article heating is important for creation of mutual diffusion of the coating and the substrate material, ensuring good adhesion and high quality of the coated layer.

In the third stage, after the articles have been heated to a given temperature, vapor or plasma fluxes of coating materials are guided to the substrate, the particles reaching the substrate surface are condensed on the surface, and a coating layer is formed from the evaporated material. In order to form complex composition coatings, reactive gas is introduced into the working chamber, usually under a pressure of 0.01-0.0001 Hg/mm. Thus, complex coatings can be generated, based on the evaporated material and reactive gas compounds. In this process, the atoms of coating material settle randomly on the substrate surface and relax to their minimal tension position under the influence of the article temperature.

If the flux contains ionized particles, negative voltages, ranging from several tens to several hundreds of volts, are applied to the substrate. In this way, the settling of the coating is concurrent with the bombardment of the surface by accelerated particles. During this process, coatings can be generated which are formed from compounds of elements that do not interact under normal conditions.

During the deposition, the atoms settle randomly on the substrate surface. At low deposition temperatures, in the absence of surface diffusion, and consequently, the absence of a transition layer in which relaxation from the substrate structure to the coating structure can take place, a drastic structure change occurs at the transition from substrate to coating. This leads to high stresses at the substrate-coating interface, and consequently to micro-cracks, splitting off, and sometimes the self-destruction of the entire coating.

One of the most serious drawbacks of ion-plasma technology for deposition wear-resistant and protective coatings, which considerably restricts the fields of its application, is the need to heat articles to temperatures of 400-450° C. in order to generate coatings with proper adhesion and performance. Relatively high temperatures make it impossible to apply coatings to machine articles made of a variety of steels having a relatively low tempering temperature (<350° C.) without changing their physical and mechanical volumetric properties. Also, known ion-plasma coating deposition methods of making hard, protective, wear-resistant thick film coatings cannot be used on articles made of materials with a relatively low melting point, such as aluminum, zinc-aluminum alloys, brass, bronze, etc., or on thin and high-precision articles which would be subject to deformation during heating. Moreover, high temperatures result in the deterioration of the performance of some coatings. For example, in the deposition of aluminum-based coatings on steels, high temperatures cause the generation of a hard, brittle diffusion layer containing an inter-metallic Fe₂A₅ composition which heavily impairs the coating's adhesion to the substrate.

Hence, the development of a coating deposition technique using PVD methods at low temperatures will not only allow the significant widening of their field of application, but will extend them to industry branches having yet to use them. Moreover, the efficiency of these methods in the traditional fields of application will be improved.

As mentioned above, the deposition of coatings that occurs simultaneously with ion bombardment is implemented in the electrical arc vacuum PVD method. However, the traditional implementation of such a method is inapplicable for coating deposition at temperatures below 400° C. This stems from the fact that in such a case, the temperature of the articles is directly, and quite strongly, related to the energy parameters of the surface ion bombardment. Keeping the temperature at a preset level, normally without exceeding the preset temperature, imposes restrictions on the possibility of varying and setting the ion flux parameters which are essential for the generation of coatings having certain structures and properties.

It is therefore a broad object of the present invention to provide a system and a method for the low temperature deposition of corrosion-proof, wear-resistant ion-plasma coatings.

In accordance with the present invention, there is provided a system for deposition of an ion plasma coating on a substrate, said system comprising a housing defining a vacuum chamber and having access means for the introduction and retrieval of a substrate to be coated; a plasma vacuum deposition (PVD) source communicating with the interior of said housing; an electrically conductive support on which said substrate is placed; a gas ion-plasma source cathode assembly communicating with said chamber in spaced-apart relationship to said support; a first power supply electrically connected to said support; a second power supply electrically connected to said cathode assembly, and a third power supply of additional discharge electrically connectable to said cathode assembly, wherein said power supplies are operative to effect pulsed discharge on said gas ion-plasma source cathode assembly or pulsed accelerating voltage on said support.

The invention further provides a method for deposition of an ion-plasma coating on a substrate, said method comprising (a) providing a housing defining a vacuum chamber and having access means for the introduction and retrieval of a substrate to be coated; a plasma vacuum deposition (PVD) source communicating with the interior of said housing; an electrically conductive support on which said substrate is placed; a low energy gas ion plasma source cathode assembly disposed in communication with said chamber in spaced-apart relationship to said support; a first power supply electrically connected to said support; a second power supply electrically connected to said cathode assembly, and a third power supply of additional discharge electrically connectable to said cathode assembly,

(b) introducing a substrate into said chamber and placing it on said support;

(c) cleaning and activating a surface of said substrate by effecting ion bombardment of its surface with an inert gas supplied to said chamber; (d) replacing at least some of said inert gas with a reactive gas and effecting ion bombardment of said surface, to condition said surface for receiving the deposition of coating material; (e) supplying plasma vapor or plasma flux material from said source to said chamber and initiating controlled pulsed additional discharge on said cathode assembly, or on said substrate, to effect the deposition of coating material on said substrate; wherein, at least during the deposition of said coating material, the period of time tₚ between pulses satisfies me expression

tₚ=δ₀/C

wherein:

δ₀ is a monatomic layer thickness of the coating material; and

C is the coating settling rate; and the pulse duration

τₚ=k* tₚ

wherein: k=ε/V*e is a coefficient equal to the ratio between the threshold energy s needed to displace an atom from the crystal lattice junction, and the product of pulse amplitude V and elementary charge e.

### BRIEF DESCRIPTION OF THE DRAWINGS

The invention will now be described in connection with certain preferred embodiments with reference to the following illustrative figures so that it may be more fully understood.

With specific reference now to the figures in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, necessary for a fundamental understanding of the invention, the description taken with the drawings making apparent to those skilled in the art how the several forms of the invention may be embodied in practice. In the drawings:

FIG. 1 is a schematic illustration of a first embodiment of the system according to the present invention;

FIG. 2 is a schematic diagram of a pulse voltage for operating the system of FIG. 1; no attempt is made to show structural details of the invention in more detail than is

FIG. 3 is a schematic illustration of a modification of the system of FIG. 1, and FIG. 4 illustrates a further embodiment of the system according to the present invention.

### DETAILED DESCRIPTION OF THE PREFERRED EMBODIMENT

A preferred embodiment of a system for the low temperature deposition of corrosion-proof, wear-resistant ion-plasma coatings is illustrated in FIG. 1. The system 1 includes a housing 2, having access means 4, e.g., a cover which may be opened, defining a vacuum chamber 6, a PVD source 8 containing a plasma or vapor substance, a substrate 10 to be coated resting on an electrically conductive support 12, and a gas ion-plasma source 14 with a cathode assembly 16, for example, a hot cathode, disposed inside. There is also provided an outlet 18 (optionally valved) leading to a vacuum pump (not shown).

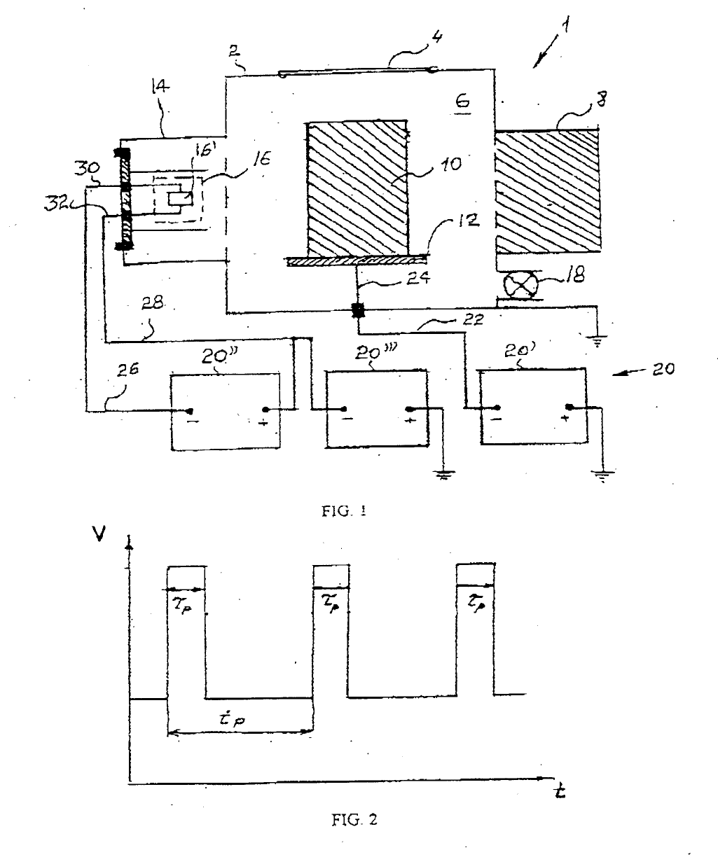

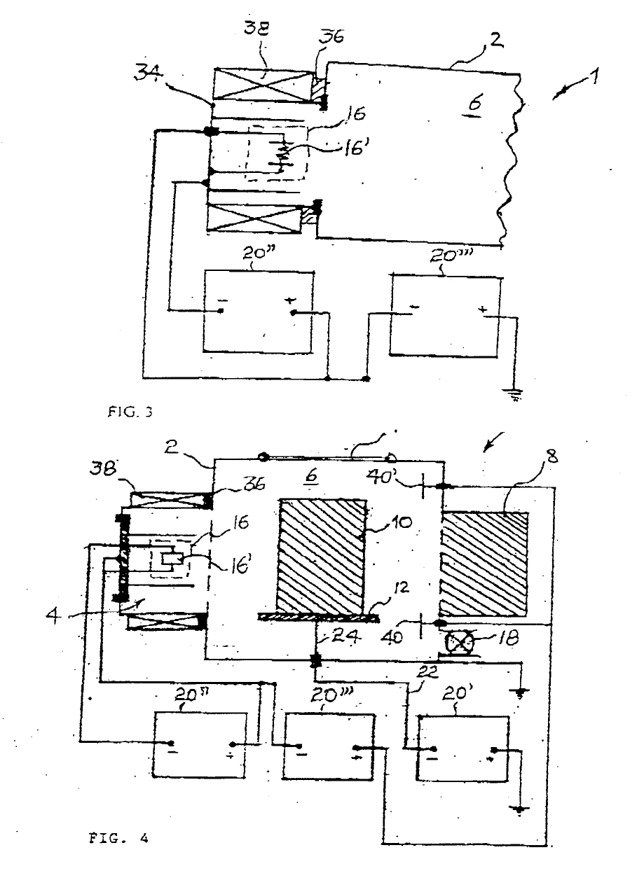

Further seen in FIG. 1 is a power supply 20 which, for illustrative purposes, is shown to include three distinct power supplies. Power supply 20′ is electrically connected, via lead 22, to the electrical terminal 24 of support 12. While the positive terminal is grounded, as is the housing 2 which serves as an anode, a possible embodiment of a gas ion-plasma source 14 includes a thermionic or hot cathode 16, preferably configured as a coil and made of a material having a high melting point, such as tungsten. Power supplies 20″ and 20′″ are electrically connected, via leads 26 and 28, to the terminals 30, 32 of the gas ion-plasma source 14 with the cathode assembly 16. Advantageously, the power supply 20′ is operable either in a DC mode, a pulse mode, or a pulsating voltage superimposed on a DC voltage mode (FIG. 2).

A modification of system 1 is shown in FIG. 3. Here, for the reduction of heating of the substrate by the hot cathode thermal radiation, the cathode 16′ is further positioned in a separate casing 34 attached to the wall of the housing 2 of the vacuum chamber 6 and communicating therewith. The housing 34 is connected to the walls of the vacuum chamber 6 in such a way that it is electrically isolated from the chamber by utilizing an insulating member 36. Outside of the casing which is made of a non-magnetic material, an electromagnetic winding 38 is arranged. One end of the cathode 16′, predominantly opposite to that end which is attached to the power supply 20″ of the gas discharge, is electrically connected to the casing 34 of the gas-ion plasma source 14. The power supply of the electromagnetic winding is not shown.

In the embodiment of FIG. 4, there are shown two anodes 40, 40′ disposed inside the chamber 6. Anodes 40, 40′ are electrically isolated from the housing 2 of the vacuum chamber 6 and are connected to the positive pole of the power supply 20′″ of the additional discharge in the gas ion-plasma source 14. The effect of such anodes is to more uniformly distribute the cathode's discharge.

System 1, with the example of a hot cathode 16′, operates as follows: Current from power supply 20″ flows via the hot cathode 16′, raising its temperature to about 3000° K., required for thermal emission of electrons. The required environment is generated inside the vacuum chamber 6, and negative voltage, with respect to the chamber body or additional anodes 40, 40′, is supplied to hot cathode 16′ from power supply 20′″. Discharge takes place on the hot cathode 16′ between the cathode and the chamber housing 4 or additional anodes 40, 40′.

The discharge on the hot cathode 16′ is constant or pulsating, depending on the operation mode of the discharge power supply 20′″.

When gas ion-plasma source 14, contained in a separate casing 34 with electromagnetic winding 38, is used (FIG. 3), current supplied by the winding power supply (not shown) flows through the winding 38 and generates a longitudinal magnetic field. The magnetic field prevents the discharge from being transferred to the walls of the casing 34 disposed across the magnetic field, and assists its distribution of the ions inside chamber 6 along the magnetic field. Connecting one terminal of the cathode 16′, opposite to that connected to the discharge supply 20′″, to the casing 34 provides a negative potential on the casing relative to different cathode parts, also preventing the emitted electrons from reaching the casing and assisting the discharge distribution inside chamber 6.

Thermo-emission cathode discharge ionizes the medium inside the vacuum chamber 6. Negative voltage from power supply source 20′ is applied between substrate 10 and the walls of the chamber. Ions of the medium, for example, inert gas ions inside the vacuum chamber, accelerated by this voltage bombard the surface of the substrate. Bombardment is permanent or pulsating, depending on the operating ˆ mode of the voltage provided by power supply 20′.

Hence, depending on the operating modes of the additional discharge power supply 20′″ and the substrate power supply 20′, the coated substrate 10 (article) can be exposed to and can adsorb on its surface the neutral atomic particles of the medium, atomic particles of the medium in ionized state, and accelerated ionized atomic particles, all according to deposition process requirements.

The method of coating a substrate according to the present invention consists of generation of vapor or plasma flux of material in vacuum using PVD techniques, and causing its deposition on the substrate, normally in a reactive gas environment. During the deposition of the coating, it is subjected to pulsed ion bombardment with ion energy up to 1000 eV (for single-charged ions), in a way that the time between pulses tₚ (pulse period) is shorter than the time of settling of a single monatomic layer of coating. In other words, the period of time tₚ between pulses satisfies the expression

tₚ=δ₀/C

wherein:

δ₀ is a monatomic layer thickness of the coating material (microns); and

C is the coating settling rate (microns/sec).

The pulse duration is selected so that the energy imparted by the accelerated ions to the substrate during the pulse will be higher than the total energy of all threshold displacements (from the junction of crystal lattice) energy of all the particles settled between the pulses. Moreover, according to this method, the preliminary ion cleaning of the substrate surface is carried out in a semi-self-maintained gas discharge, with the substrate serving as a cathode and with additional gas discharge on the hot cathode of the gas ion-plasma source or with alternative gas plasma source.

In one preferred implementation of the method according to the invention using PVD techniques of vapor or plasma flux generation, negative pulsed accelerating voltage is applied to the substrate with an amplitude up to 1000 V, a pulse period

tₚ=δ₀/C

and a pulse duration

τₚ=k*tₚ

wherein:

k=ε/V*e is a coefficient equal to the ratio between the threshold energy s needed to displace an atom from the crystal lattice junction, and the product of pulse amplitude V and elementary charge e (namely, the energy of a single ion accelerated by voltage V).

Usually, the coefficient k for the discussed range is between 1/50 to 1/100 (in practice, it can be taken as 1/50), and when the settled material flux ionization level is insufficient, an additional discharge is ignited on a cathode in the reactive or inert gas.

Atomic particles in the settled material flux which are ionized either during the flux formation, for example, in an arc method, or in an additional discharge on a cathode and accelerated by the voltage applied to the substrate during the pulse, bombard the surface of the growing coating or of the substrate at the initial stage.

Hence, pulsating ion bombardment of the surface is effected at a frequency that corresponds to the frequency of the pulsed accelerating voltage. For this case, the density of the settled material flux is nearly equal to that of the bombarding ions flux (since it is the same flux). It is apparent that W, the total energy of displacement threshold energy 8 of particles settled during the pulse period tₚ, is as follows:

W=tₚ*Cₐ*ε

wherein:

Cₐ is the number of particles reaching the surface in a time unit.

Moreover, E, the total energy of the bombarding particles during the pulse duration τₚ, will be as follows:

E=τₚ*V*e*Cₐ

Hence, from the relation E>W, it follows that

τₚ>tp*ε/V*e

wherein the coefficient ε/V*e can be taken as 1/50.

In any case, the coating deposition process starts from the cleaning and surface activation stage. The additional discharge on the hot cathode is maintained either in permanent or pulsating mode only during the accelerating voltage pulses. In this embodiment of the routine for ion cleaning prior to coating, if using, for example, a thermoemission cathode, the temperature of the cathode is elevated in order to provide the required thermal emission of electrons, applying negative voltage (relative to anode) of several tens of volts and the discharge is ignited in the inert gas environment. Pulsating or direct accelerating negative voltage of up to 1500 V is applied to the substrate. The gas atoms ionized in the discharge are accelerated by the applied voltage and bombard the substrate surface. In this manner, the ion sputtering is effected along with the surface cleaning from impurities and activation of surface atom layers. Then, the deposition stage is performed.

Ion bombardment during coating deposition in pulsating mode is advantageously used with energies up to 1000 eV and pulse duration τₚ>tₚ/50 applied at intervals of τₚ=δ₀/C. In this case, during the pulse application the accelerated atoms bombard the substrate surface, thus exciting atoms in the surface layer created by random settlement of the deposited material particles in the time intervals between pulses. Following this, the excited atoms relax to a thennodynamically more stable state on the surface. In this manner, the coating, which is formed layer by layer, features lower internal stresses and high performance.

The energy of bombarding ions is selected in order to provide the following:

The coefficient of sputtering much lower than 1. Therefore, ion bombardment does not lead to significant ion sputtering and decrease in the coating settling rate, and does not disturb the stoichiometry of the coating as a result of sputtering.

The accelerated ions penetrate only to the depth of one or two monolayers. They have no additional effects on the deeper, previously formed coating layers and actually excite only the atoms in the surface layers.

The bombarding ions' total energy is sufficient for excitation of surface atoms.

It should be noted that the efficiency and adequacy of ion bombardment parameters, supported by experiments, showed that when the pulse duration, and consequently the pulses' on-ofF time ratio, are close to the minimal possible values (τₚ″ tp), the thermal load on the substrate is moderate and the substrate temperature increase on account of ion bombardment is small. In other words, coatings with high wear-resistance and other qualities can be formed, independent of the substrate temperature. Hence, ion etching, either at moderate accelerating voltages or in a pulsating mode, makes it possible to prevent substrate heating during the ion cleaning stage and to carry out the procedure at low substrate temperatures. The above two factors, namely, ion bombardment in pulse mode with preset parameters during the coating settling, and preliminary ion cleaning in a semi-self-maintained gas discharge with an additional discharge in gas ion-plasma source, enable forming of coatings with the required structure, on the one hand, and adequate preliminary ion cleaning and surface activation, regardless of the substrate temperature, on the other.

Moreover, during preliminary ion cleaning of the substrate surface in a semi-self-maintained discharge in inert gas with an additional discharge on a cathode, the discharge envelops the entire substrate surface on all sides and the inert gas atom particles ionized in the additional discharge on the cathode and accelerated by the voltage applied to the substrate, bombard the surface and provide for ion cleaning through sputtering and surface atoms activation. Here, the ion flux density on the surface can be controlled through the parameters of the additional discharge and their energy, through the voltage applied to the substrate, as opposed to a self-maintained glow discharge in which the parameters are quite strictly determined by the physics of its glow. Hence, a quite simple and controlled process of ion cleaning of surfaces is provided. The semi-self-maintained gas discharge provides for substrate etching, even at moderate acceleration voltages.

The present invention also includes an additional technological improvement, as follows: After ion cleaning and before coating deposition, there is a possibility to saturate the substrate surface with reactive gas in semi-self-maintained gas discharge with an additional discharge on a cathode in reactive gas or a mixture of reactive and inert gases environment, with pulsating or direct voltages applied to the substrate and to the additional discharge cathode. Here, the gas discharge parameters have to be selected so that the concentration of the reactive gas atoms on the substrate surface will not be higher than the solubility limit of this gas in the substrate material. After the substrate saturation with reactive gas, a short duration ion cleaning is carried out in inert gas environment. In this variation of the method, the reactive gas particles ionized in semi-self-maintained discharge with additional discharge on a cathode, are accelerated and, after reaching the surface, enter into reaction with the substrate, thus forming a surface layer saturated with active gas.

The request to stay below the limit of gas solubility in the substrate material stems from the fact that, in this case, a solid solution of the reactive gas is created in the substrate material, without generation of a layer of chemical compounds of the gas ions with the substrate material atoms, which might impair the adhesion of the deposited layer. On forming the near-surface layer saturated with reactive gas atoms, a short duration ion cleaning is performed in order to remove the traces of chemical compounds of reactive gas with substrate material from the surface. Hence, a near-surface layer is formed on the substrate surface, which is saturated with active gas, such as nitrated or cemented. Such a layer forms an interface between the substrate and the coating. Operational features of these coatings with an under-layer are likely to be much better than that of the coatings deposited on the original surface.

The method of coating a substrate according to the present invention is as follows: Inert gas, such as Ar, is supplied to the vacuum chamber 6 and additional discharge is ignited on the cathode of the gas ion plasma source. The gas atoms in the discharge are ionized, and accelerating voltage is applied to the substrate 10. Ions bombard the substrate surface, causing sputtering, effecting cleaning and activation of the substrate surface. In order to reduce the probability of generation of micro-arcs on the substrate surface, ion cleaning is started at a low accelerating voltage, which is gradually increased until the required value is attained. In order to limit the substrate temperature, the ion cleaning is effected in a pulse mode by setting the accelerating power supply, or by turning the supply of the additional discharge to the cathode, to a pulse mode. For more efficient cleaning, in the intervals between pulses the substrate surface can be subjected to low energy or low density ion irradiation, through setting the substrate power supply or additional discharge power supply mode to the pulsed voltage superimposed on the DC voltage.

After ion cleaning as described above, the inert gas is replaced with reactive gas, or a mixture of reactive and inert gases. The reactive gas ions reaching the surface react with it and form a near-surface layer saturated with reactive gas ions. This process is activated by ion bombardment. On generation of a near-surface layer saturated with reactive gas ions, the technological parameters are set to restrict the ion concentration on the surface to the limits of solubility of the respective gas in the substrate material. In this event, solid solution of gas in the substrate material is generated, whereas a layer of gas ions chemically bound with the substrate atoms, which might impair the adhesion of the coating deposited on the substrate, is not generated. On forming the near-surface layer saturated with reactive gas atoms, short duration ion cleaning is usually performed to remove from the surface the traces of chemical compounds of the reactive gas with substrate matter.

Then, PVD vapor or plasma flux from source 8 is turned ON, and if required, additional discharge on the cathode 16′ of the gas ion plasma source is provided. If necessary, chamber 6 is filled with reactive gas. The particles in the material and reactive gas flux that reach the substrate 10 are condensed and form a coating. During the coating process, settling pulsed ion bombardment is effected by selecting the appropriate operation modes of the substrate power supply (ion accelerating voltage) and the additional discharge in gas ion-plasma source is effected. To improve the reactivity of the particles, in the time interval between pulses the substrate is subjected to lower energy or low density ion radiation, through setting the substrate power supply and additional discharge power supply modes to pulsating voltage superimposed on the direct voltage. The surface is cleaned and activated prior to coating deposition, and the coating is formed with an under-layer saturated with atoms of reactive gas.

It will be evident to those skilled in the art that the invention is not limited to the details of the foregoing illustrated embodiments and that the present invention may be embodied in other specific forms without departing from the spirit or essential attributes thereof. The present embodiments are therefore to be considered in all respects as illustrative and not restrictive, the scope of the invention being indicated by the appended claims rather than by the foregoing description, and all changes which come within the meaning and range of equivalency of the claims are therefore intended to be embraced therein.

What is claimed is:

1. A method for deposition of an ion-plasma coating on a substrate, said method comprising:
a. providing a housing defining a vacuum chamber and having access means for the introduction and retrieval of a substrate to be coated; a physical vapor deposition (PVD) source communicating with the interior of said housing; an electrically conductive support on which said substrate is placed; a low energy gas ion plasma source cathode assembly disposed in communication with said chamber in spaced-apart relationship to said support; a first power supply electrically connected to said support; a second power supply electrically connected to said cathode assembly, and a third power supply electrically connectable to said cathode assembly,
b. introducing a substrate into said chamber and placing it on said support;
c. cleaning and activating a surface of said substrate by effecting ion bombardment of its surface with an inert gas ions supplied to said chamber;
d. replacing at least some of said inert gas with a reactive gas, and effecting ion bombardment of said surface, to condition said surface for receiving the deposition of coating material;
supplying, coating material vapor or plasma flux from said PVD source to said chamber and initiating controlled pulsed additional discharge on said cathode assembly, or on said substrate, to effect the deposition of coating material on said substrate;
f. performing the process of deposition of the said coating material on the said substrate in two phases in order to facilitate deposition of a high quality hard wear resistant coating on a substrate having a sufficiently low temperature:
1. at relatively low substrate bias voltage, depositing a thin (monoatomic) layer during the time interval between pulses;
2. at much higher bias voltage during the pulse duration, bringing to the deposited layer enough energy to “settle” the layer and to ensure its properties, through a “momentary” heating of the said layer by energetic ions flow,
g. repeating this “two phase” sequence long enough to build a coating of required thickness,
wherein at least during the deposition of said coating; material, the period of time tp between pulses satisfies the expression
tₚ=δ₀/C
wherein:
δ₀ is a monatomic layer thickness of the coating material, and
C is the coating settling: rate,
and the pulse duration
τₚ=k*tₚ
wherein:
k=å/V*e is a coefficient equal to the ratio between the threshold energy å needed to displace an atom from the crystal lattice junction, and the product of pulse amplitude V and elementary charge e.

2. The method as claimed in claim 1, wherein accelerating voltage to said substrate or said cathode additional discharge is generated as either a DC, pulsating, or pulsating voltage superimposed on a DC voltage.

3. The method as claimed in claim 1, wherein cleaning and/or deposition arc effected at a pulse discharge conforming to the expression
wherein:
δₚ is the pulse duration, and
tₚ is the period of time between pulses,

4. A system for deposition of an ion plasma coating on a substrate, made for implementation of coating method as claimed in claims 1 to 3, said system comprising:
a housing defining a vacuum chamber and having access means for the introduction and retrieval of a substrate to be coated;
a Physical Vapor Deposition (PVD) source communicating with the interior of said housing;
an electrically conductive support on which said substrate is placed;
a gas ion-plasma source cathode assembly communicating with said chamber in spaced-apart relationship to said support;
a first power supply electrically connected to said support;
a second power supply electrically connected to said cathode assembly, and
a third power supply of additional discharge electrically connectable to said cathode assembly;
wherein said power supplies are operative to effect pulsed discharge on said gas ion-plasma source cathode assembly or pulsed accelerating voltage on said support.

5. The system as claimed in claim 4, wherein at least one of said power supplies is capable of operating in either DC, pulsating, or pulsating voltage superimposed on a DC voltage, modes.

6. The System as claimed in claim 4, further comprising a winding for generating a longitudinal magnetic field about said cathode assembly to assist the even distribution of the discharge inside said chamber, having an annular configuration disposed outside said gas ion-plasma source housing and electrically connected to at least said third power supply of additional discharge.

7. The system as claimed in claim 4, further comprising at least one anode electrically connectable to at least said third power supply and disposed inside said chamber to enhance the uniform distribution of said additional discharge.
